(19) United States
(12) Patent Application Publication
(10) Pub. No.: US 2020/0243342 A1
(43) Pub. Date: Jul. 30, 2020

(54) METHOD OF FORMING CAVITY BASED ON DEEP TRENCH EROSION

(71) Applicant: CSMC TECHNOLOGIES FAB2 CO., LTD., Wuxi New District, Jiangsu (CN)

(72) Inventors: Jiale SU, Wuxi (CN); Changfeng XIA, Wuxi (CN); Guoping ZHOU, Wuxi (CN); Xinwei ZHANG, Wuxi (CN)

(21) Appl. No.: 16/646,946

(22) PCT Filed: Aug. 14, 2018
(86) PCT No.: PCT/CN2018/100330

§ 371 Date: Mar. 12, 2020

(30) Foreign Application Priority Data
Aug. 14, 2017 (CN) 201710692827.7

(51) Int. Cl. H01L 21/3065; H01L 21/02

(52) U.S. Cl. CPC H01L 21/3065; H01L 21/02532

(57) ABSTRACT

A method of forming a cavity based on a deep trench erosion, comprising: providing a semiconductor substrate (200), and performing the deep trench erosion to the semiconductor substrate to form an array of a plurality of trenches (201) in the semiconductor substrate (200), a pitch (D1) between the outermost grooves in the array being greater than a pitch (D2) between the remaining trenches in the array; and preforming an annealing treatment to the semiconductor substrate (200) to form a cavity (202) in the semiconductor substrate (200).

### TECHNICAL FIELD

The present disclosure relates to semiconductor manufacturing process, and more particularly relates to a method of forming a cavity based on a deep trench erosion.

### BACKGROUND

When a pressure sensor uses a silicon thin film as a piezoresistive film, the silicon thin film needs to be obtained by forming a cavity on a silicon substrate. Methods of forming a cavity on a silicon substrate include the followings: 1) corroding a backside of the silicon substrate with KOH to form the cavity; 2) a cavity of Silicon-on-insulator (cavity-SOI) process; and 3) an epitaxial cavity process. In a KOH erosion process, the deep trench erosion is made from the backside, and the remaining silicon at the bottom of the deep trench then forms the silicon thin film. Since the side walls of the deep trench corroded by KOH are inclined at an angle of 54 degrees and sides of the deep trench are shaped in an inverted trapezoid, the area of a die is larger than that of the silicon thin film actually required. Therefore, the number of dies produced from a single wafer is small and the cost is high. In the cavity SOI process, the area of the die is greatly reduced by dry etching, and the number of dies produced from the single wafer is greater than that in the KOH erosion process. But because Si—Si bonding is required in the cavity SOI process, the cost of the process is high and the production period is long. The epitaxial cavity process is a surface process, in which the deep trench is etched first and then a top portion is sealed by growth epitaxy, which is simpler and lower in cost than the cavity SOI process. But since the epitaxial silicon is polysilicon, the quality of the piezoresistive film is not as good as that of monocrystal silicon.

Therefore, it is necessary to provide a method to address the above-mentioned problems.

### SUMMARY

According to various embodiments of the present application, there is provided a method of forming a cavity based on a deep trench erosion, comprising: providing a semiconductor substrate, and performing the deep trench erosion to the semiconductor substrate to form an array of a plurality of trenches in the semiconductor substrate, a pitch between the outermost trenches in the array being greater than a pitch between the remaining trenches in the array; and performing an annealing treatment to the semiconductor substrate to form a cavity in the semiconductor substrate.

Details of one or more embodiments of the present disclosure are set forth in the drawings and description. Other features, objects and advantages of the present disclosure will become apparent from the specification, drawings and claims.

### BRIEF DESCRIPTION OF THE DRAWINGS

For better describing and illustrating the embodiments and/or examples of those disclosures herein, it may refer to one or more drawings. Additional details or examples used to describe the drawings should not be regarded as limiting the scope of any of the present disclosure, the presently described embodiments and/or examples, and the presently understood best mode of these disclosures.

FIGS. 1A-1D are schematic cross-sectional views of devices respectively obtained according to steps sequentially implemented by an existing cavity formation process;

FIGS. 2A-2C are schematic cross-sectional views of devices respectively obtained according to steps sequentially implemented by a method of the present disclosure exemplary embodiment;

FIG. 3 is a top view of the trench 201 shown in FIG. 2A;

FIGS. 4(a)-4(b) are schematic views of cavities respectively formed in the cases of the pitch D1=D2 and D1>D2 of the trench 201 shown in FIG. 3;

FIG. 5 is a flowchart according to steps sequentially implemented by a method of the present disclosure exemplary embodiment.

### DETAILED DESCRIPTION OF THE EMBODIMENTS

In order to facilitate understanding of the present disclosure, the present disclosure will be more fully described with reference to the relate drawings below. Preferred embodiments of the present disclosure are shown in the drawings. However, the present disclosure may be implemented in many different forms and is not limited to the embodiments described herein. Conversely, the purpose of providing these embodiments is to make the content of the present disclosure more thorough and comprehensive.

Unless otherwise defined, all technical and scientific terminologies used herein have the same meaning as generally understood by those skilled in the art belonging to the present disclosure. The terminologies used herein in the specification of the present disclosure are only for the purpose of describing specific embodiments, and not intended to limit the present disclosure. The terminologies “and/or” used herein include any and all combinations of one or more related listed items.

In order to understand the present disclosure thoroughly, detailed steps and structures will be set forth in the following description, so as to explain the technical solution set forth in the present disclosure. The preferred embodiments of the present disclosure are described in details below. However, in addition to these detailed descriptions, the present disclosure may have other implementations.

Conventional silicon cavity formation process at lower cost generally includes the following steps:

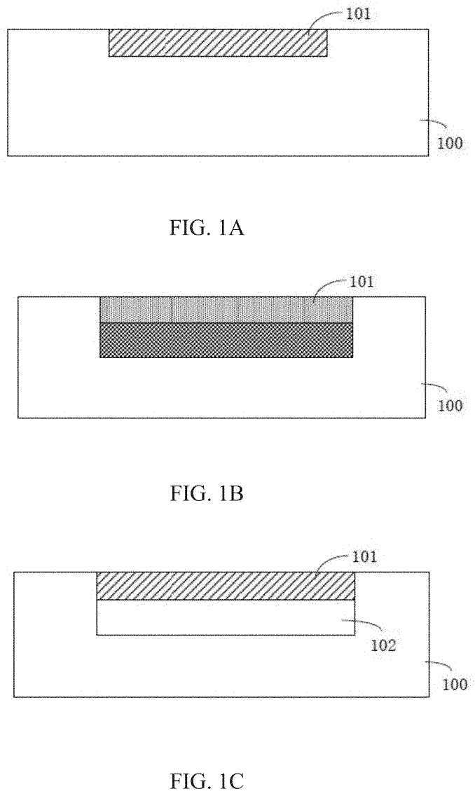

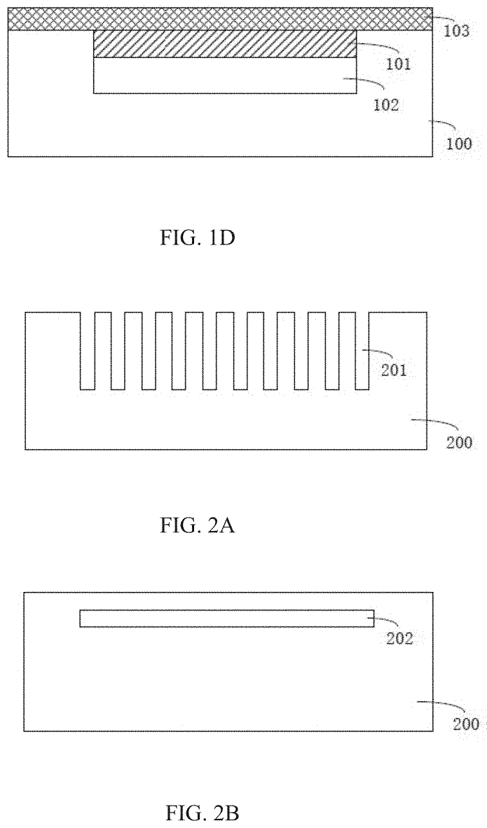

First, as shown in FIG. 1A, a silicon substrate 100 is provided. P-impurities are doped in the silicon substrate 100. An n+ impurity injection region 101 is formed in an upper portion of the silicon substrate 100 by an ion implantation process. Specifically, after a mask having an ion implantation window pattern is formed on the silicon substrate 100, the n+ impurity injection region 101 is formed in the upper portion of the silicon substrate 100 by the ion implantation process, and then the mask having the ion implantation window pattern is removed by a liftoff process.

Next, as shown in FIG. 1B, the silicon substrate 100 is immersed in a concentrated HF solution, and a voltage and a current are applied to the surface of the silicon substrate 100. A porous silicon with a relatively small aperture is formed in the n+ impurity injection region 101. A porous silicon with a relatively large aperture is formed in a p-doped region below the n+ impurity injection region 101.

Next, as shown in FIG. 1C, the silicon substrate 100 is took out of the concentrated HF solution and annealed at a high temperature in a hydrogen environment. The porous silicon formed in the n+ impurity injection region 101 is fused together, while the porous silicon formed in the p-doped region below the n+ impurity injection region 101 forms a cavity 102.

Next, as shown in FIG. 1D, a silicon layer 103 with a certain thickness is epitaxially grown on the surface of the silicon substrate 100 to meet product requirements.

The main disadvantage of the process described above is that the silicon wafer needs to be immersed in the concentrated HF solution and energized. The process is complicated and dangerous, special equipment and process are required, and the cost is high.

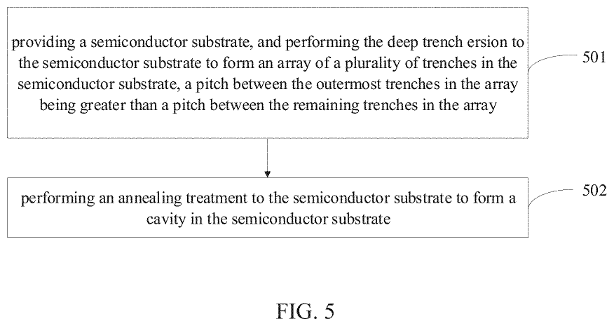

In order to address shortcomings existing in the existing silicon cavity formation process, as shown in FIG. 5, a method of forming a cavity based on a deep trench erosion is provided in the present disclosure, the method includes:

In step 501, a semiconductor substrate is provided, and the deep trench erosion is performed to the semiconductor substrate to form an array of a plurality of trenches in the semiconductor substrate, in which a pitch between the outermost trenches in the array is greater than a pitch between the remaining trenches in the array;

In step 502, an annealing treatment is performed to the semiconductor substrate to form a cavity in the semiconductor substrate.

According to the method of forming the cavity based on the deep trench erosion set forth in the present disclosure, the area of a die may be reduced, the process difficulty may be reduced, and the cost may be reduced.

In order to understand the present disclosure thoroughly, detailed structures and/or steps will be set forth in the following description, so as to explain the technical solutions set forth in the present disclosure. The preferred embodiments of the present disclosure are described in details below. However, in addition to these detailed descriptions, the present disclosure may have other implementations.

### [Exemplary Embodiment]

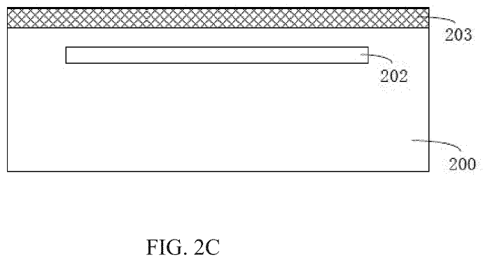

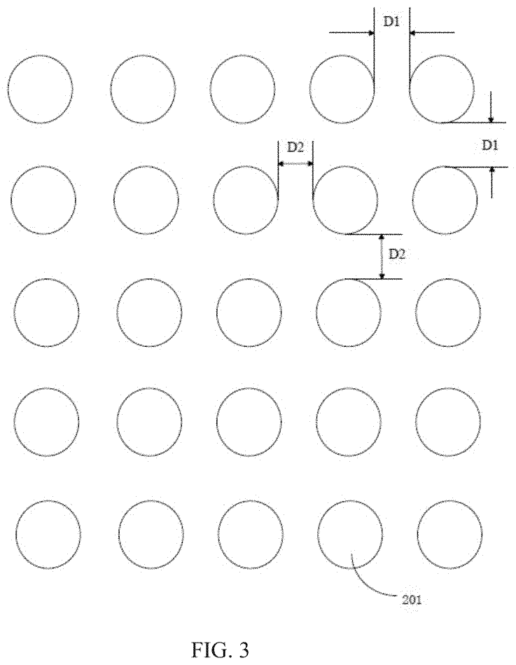

Referring to FIGS. 2A-2C, the schematic cross-sectional views of devices respectively obtained according to steps sequentially implemented by the method of the present disclosure exemplary embodiment are shown.

First, as shown in FIG, 2A, a semiconductor substrate 200 is provided. A constituent material of the semiconductor substrate 200 contains silicon, such as undoped monocrystal silicon, impurity-doped monocrystal silicon, silicon on insulator (SOI), stacked silicon on insulator (SSOI), stacked silicon germanium on insulator (S-SiGeOI), silicon germanium on insulator (SiGeOI), or the like. As an example, in the present embodiment, the monocrystal silicon is selected as the constituent material of the semiconductor substrate 200.

Next, the deep trench erosion is performed to the semiconductor substrate 200, so as to form an array of a plurality of trenches 201 in the semiconductor substrate 200. As an example, first a mask layer having a pattern of the array is formed on the semiconductor substrate 200, and then the semiconductor substrate 200 is etched using the mask layer as a mask to form the array of a plurality of trenches 201 in the semiconductor substrate 200. The etching is a conventional dry etching , and then the mask layer is removed using a conventional liftoff process.

A feature size of the trench 201 is 0.5 micron to 1.0 micron, an erosion depth of the trench 201 is 1.0 micron to 20.0 microns, and the pitch of the trench 201 is 0.5 micron to 1.0 micron. A shape of the trench 201 may be circular as shown in FIG. 3, or may also be square or other shapes. As an example, when the shape of the trench 201 is circular, its feature size refers to diameter, and when the shape of the trench 201 is square, its feature size refers to diagonal line.

Next, as shown in FIG. 2B, an annealing treatment is performed to the semiconductor substrate 200 to form a cavity 202 in the semiconductor substrate 200. As an example, the annealing is implemented in a non-oxygen environment (e.g. in a hydrogen or nitrogen environment, or the like), and the annealing temperature is above 800° C. Because of the high temperature and non-oxygen environment, the silicon atoms in the semiconductor substrate 200 migrate, and the cavity 202 is eventually formed.

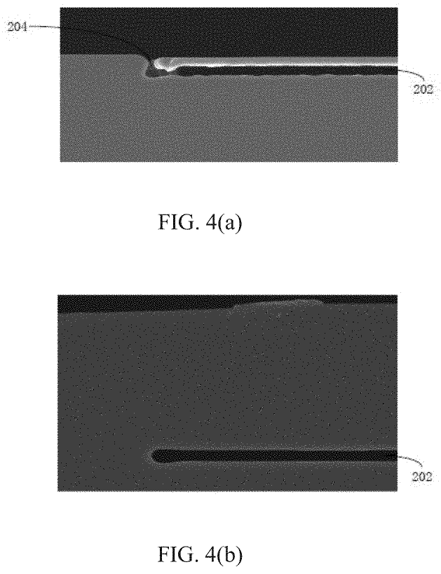

As shown in FIG. 3, when the pitch D1 between the outermost trenches 201 in the array is equal to the pitch D2 between the remaining trenches 201 in the array, a gap 204 as shown in FIG. 4(a) may be formed at the edge of the cavity 202 finally formed.

To avoid forming the gap 204 as shown in FIG. 4(a) at the edge of the cavity 202 finally formed, the pitch D1 between the outermost trenches 201 in the array is set to be greater than the pitch D2 between the remaining trenches 201 in the array according to the present disclosure. After implementing the annealing treatment as above discussed, the gap 204 shown in FIG. 4(a) is not formed at the edge of the cavity 202 finally formed, as shown in HG. 4(b).

In addition, by changing the size of the pitch D2 between the trenches 201 which constitute the array, after the annealing treatment above is implemented, single cavity 202 having different feature sizes may be formed. The pitch D1 and D2 both vary in range of 0.5 micron to 1.0 micron. The greater the pitch D2 is, the higher the temperature of the annealing treatment is. A duration of the annealing treatment does not exceed 20 minutes. At the same time as the pitch D2 is changed, the pitch D1 need to be adjusted to be greater than D2 to ensure that the gap 204 as shown in FIG. 4(a) is not formed at the edge of the cavity 202 finally formed.

Next, as shown in FIG. 2C, an epitaxial material layer 203 is formed on the semiconductor substrate 200 to meet product requirements. A constituent material of the epitaxial material layer 203 contains silicon. As an example, the epitaxial material layer 203 is formed by a conventional epitaxial growth process. The thickness of the epitaxial material layer 203 is 10.0 microns to 50.0 microns to ensure that a film layer having a certain thickness above the cavity 202 serves as a piezoresistive film of a pressure sensor.

So far, the process steps implemented according to the method of the present disclosure exemplary embodiment are completed. Compared with the conventional process, the method of forming the cavity based on the deep trench erosion according to the disclosure can reduce the area of the die and is compatible with the existing CMOS process without adding any new equipment, thereby reducing the process difficulty and lowering the cost.

It may be understood that the semiconductor device manufacturing method in the present disclosure includes not only the steps as above, but can also include other required steps before, during or after the steps as above, which all fall within the scope of the manufacturing method of the present embodiment.

As an example, a front end device is formed on the semiconductor substrate 200. For simplification, it is not shown in the drawings. The front end device refers to a device which is formed before a back end of line (BEOL) is implemented to the semiconductor device. A specific structure of the front end device is not limited herein. The front end device includes a gate structure, As an example, the gate structure includes gate dielectric layers and gate material layers stacked in sequence from bottom to top. Side wall structures are formed on both sides of the gate structure. Source/drain regions are formed in the semiconductor substrate 200 on both sides of the side wall structure. Channel regions are formed between the source/drain regions; Self-alignment silicide is formed on the top of the gate structure and on the source/drain regions.

As an example, the gate dielectric layer includes an oxide layer, such as a silicon dioxide (SiO₂) layer. The gate material layer includes one or more of a polycrystalline silicon layer, a metal layer, an electrical conductivity metal nitride layer, an electrical conductivity metal oxide layer and a metal silicide layer, wherein a constituent material of the metal layer may include wolfram (W), nickel (Ni) or titanium (Ti); the electrical conductivity metal nitride layer includes a titanium nitride (TiN) layer; the electrical conductivity metal oxide layer includes an iridium oxide (IrO₂) layer; the metal silicide layer includes a titanium silicide (TiSi) layer. The formation method of the gate dielectric layer and the gate material layer may use any existing technology familiar to those skilled in the art, preferably chemical vapor deposition (CVD), such as low-temperature chemical vapor deposition (LTCVD), low-pressure chemical vapor deposition (LPCVD), rapid thermal chemical vapor deposition (RTCVD), plasma-enhanced chemical vapor deposition (PECVD).

The technical features of the above-described embodiments may be arbitrarily combined, and not all possible combinations of the respective technical features in the above embodiments are described for the sake of brevity of the description. However, as long as the combinations of these technical features are not contradictory, they should be considered to be within the scope of this specification.

The above-described embodiments represent only a few implementations of the present disclosure, the description of which is more specific and detailed, but is not therefore to be understood as limiting the patent scope of the present disclosure. It should be noted that several modifications and improvements may be made to those ordinary skilled in the art without departing from the present disclosure concept, all of which fall within the scope of the present disclosure. Therefore, the protection scope of the present disclosure patent shall be subject to the appended claims.

1. A method of forming a cavity based on a deep trench erosion, comprising:
providing a semiconductor substrate, and performing the deep trench erosion to the semiconductor substrate to form an array of a plurality of trenches in the semiconductor substrate, a pitch between the outermost trenches in the array being greater than a pitch between the remaining trenches in the array; and
performing an annealing treatment to the semiconductor substrate to form a cavity in the semiconductor substrate.

2. The method according to claim 1, wherein after forming the cavity, the method further comprising:
forming an epitaxial material layer on the semiconductor substrate.

3. The method according to claim 2, wherein the epitaxial material layer is formed by an epitaxial growth process.

4. The method according to claim 2, wherein the thickness of the epitaxial material layer is 10.0 microns to 50.0 microns.

5. The method according to claim 2, wherein a material of the epitaxial material layer contains silicon.

6. The method according to claim 1, wherein a feature size of the trench is 0.5 micron to 1.0 micron.

7. The method according to claim 1, wherein an erosion depth of the trench is 1.0 micron to 20.0 microns.

8. The method according to claim 1, wherein the pitch of the adjacent trenches is 0.5 micron to 1.0 micron.

9. The method according to claim 1, wherein a shape of the trench is circular.

10. The method according to claim 1, wherein a shape of the trench is square.

11. The method according to claim 1, wherein the annealing is implemented in a non-oxygen environment.

12. The method according to claim 11, wherein the annealing is implemented in a hydrogen environment.

13. The method according to claim 11, wherein the annealing is implemented in a nitrogen environment.

14. The method according to claim 1, wherein the annealing temperature is above 800° C.

15. The method according to claim 1, wherein by changing the size of the pitch between the trenches which constitute the array, after the annealing treatment is implemented, single cavity having different feature sizes are formed.

16. The method according to claim 15, wherein the greater the pitch between the trenches is, the higher the temperature of the annealing treatment is.

17. The method according to claim 1, wherein a material constituting the semiconductor substrate contains silicon.

18. The method according to claim 1, wherein the deep trench erosion is a dry etching.

19. The method according to claim 1, wherein a duration of the annealing treatment does not exceed 20 minutes.

20. The method according to claim 1, wherein a front end device is formed on the semiconductor substrate, and the front end device comprises a gate structure.
